(19) United States
(12) Patent Application Publication
(10) Pub. No.: US 2026/0371622 A1
(43) Pub. Date: Nov. 19, 2026

(54) THREE-DIMENSIONAL MOS CAPACITOR APPLICATIONS

(71) Applicant: Micron Technology, Inc., Boise, ID (US)

(72) Inventors: Srinivas Pulugurtha, Boise, ID (US); Michael James Irwin, Boise, ID (US); Tuan Khanh Chau, Meridian, ID (US); Rekha Chithra Thomas, Hyderabad (IN); Sonam Jain, Boise, ID (US)

(21) Appl. No.: 19/212,158

(22) Filed: May 19, 2025

(51) Int. Cl. H10D 1/66; H10B 12/00; H10D 1/00; H10D 64/66

(52) U.S. Cl. CPC H10D 1/665; H10B 12/50; H10D 1/047; H10D 64/661

(57) ABSTRACT

A variety of applications can include an integrated circuit having a three-dimensional metal-oxide-semiconductor capacitor in semiconductor material such that the semiconductor material is not an element of the metal-oxide-semiconductor capacitor. The metal-oxide-semiconductor capacitor can be realized by a polysilicon-dielectric-polysilicon structure in a dielectric trench-like in semiconductor region in the substrate of an integrated circuit. The integrated circuit can be a memory die. The memory die can be a NAND memory die. A metal-oxide-semiconductor capacitor in a trench-like dielectric can have a depth in the integrated circuit independent of the depth of a shallow trench isolation for the metal-oxide-semiconductor capacitor in the integrated circuit.

### FIELD OF THE DISCLOSURE

Embodiments of the disclosure relate generally to integrated circuits, and more specifically, to memory devices and formation thereof.

### BACKGROUND

Memory devices are typically provided as internal, semiconductor, integrated circuits in computers or other electronic devices. There are many different types of memory, including volatile and non-volatile memory. Volatile memory requires power to maintain its data, and includes random-access memory (RAM), dynamic random-access memory (DRAM), static RAM (SRAM), or synchronous dynamic random-access memory (SDRAM), among others. Non-volatile memory can retain stored data when not powered and includes flash memory, read-only memory (ROM), electrically erasable programmable ROM (EEPROM), erasable programmable ROM (EPROM), resistance-variable memory, such as phase-change random-access memory (PCRAM), resistive random-access memory (RRAM), magnetoresistive random-access memory (MRAM), or three-dimensional (3D) XPoint™ memory, among others. Properties of memory devices and other electronic devices can be improved by enhancements to the design and fabrication of components of the electronic devices such as, but not limited to, capacitors in an integrated circuit for the electronic devices.

### BRIEF DESCRIPTION OF THE DRAWINGS

The drawings, which are not necessarily drawn to scale, illustrate generally, by way of example, but not by way of limitation, various embodiments discussed in the present document.

FIG. 1 is a cross-sectional representation of two example capacitors in an integrated circuit separated from each other by a shallow trench insulator.

FIG. 2 illustrates an example structure having a capacitor that can be implemented in an integrated circuit without using a semiconductor substrate or well as a component of capacitor, in accordance with various embodiments.

FIG. 3 is a cross-sectional representation of two example capacitors in an integrated circuit separated from each other by a shallow trench insulator, where the capacitors are structured in a semiconductor material without the semiconductor material being a part of either capacitor, in accordance with various embodiments.

FIG. 4 is a flow diagram of features of an example method of forming an integrated circuit, in accordance with various embodiments.

FIGS. 5-11 represent an example process flow of forming a three-dimensional metal-oxide-semiconductor capacitor in a portion of an integrated circuit, in accordance with various embodiments.

FIG. 12 is schematic of an example memory device that can include an architecture in which three-dimensional metal-oxide-semiconductor capacitors are structured in a periphery to a memory array of the example memory device, in accordance with various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments can be utilized, and structural, logical, mechanical, and electrical changes can be made to these embodiments. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above. Various features can have a vertical component to the direction of their structure. The various embodiments are not necessarily mutually exclusive, as some embodiments can be combined with one or more other embodiments to form new embodiments. The following detailed description is, therefore, not to be taken in a limiting sense.

A capacitor can be structured in an integrated circuit, such as a memory die, as a 3D metal-oxide-semiconductor (MOS) capacitor. A typical 3D MOS capacitor in an integrated circuit is configured as a metal or polysilicon separated from a silicon substrate or silicon well by a dielectric that can be a trench-like structure in which the metal or polysilicon is located. The metal of a MOS structure can doped polysilicon having a low resistivity. The capacitance is provided by the metal or polysilicon/dielectric/silicon arrangement. Generally, a MOS capacitor has three regions of operation: accumulation, depletion, and inversion with respect to the applied voltage. When a capacitor is built in an integrated circuit, there is a voltage sensitivity associated with the capacitor. For example, a capacitor can be structured to have an operational voltage range in the integrated circuit in which the capacitor is formed, where the operational voltage range is between +N volts and −M volts, where N and M are positive numbers. The capacitor may have a higher capacitance at +N volts and a lower capacitance at −M volts. The difference in capacitance between the capacitance at +N volts, C(V=+N), and the capacitance at −M volts, C(V=−M), is defined herein as capacitance-voltage (C−V) roll-off.

In operation of a capacitor in an integrated circuit, such as a memory die, it is desired that the capacitance is in the inversion operation region where the capacitance is uniformly constant (flat) over the operational voltage range, which corresponds to a zero C−V roll-off. Conveniently, in an approach to provide a flat capacitance profile, the silicon directly adjacent the dielectric of the typical 3D MOS capacitor can be doped with a doping profile from the surface of the silicon to a doping depth that is less than the depth of the dielectric trench-like structure in the silicon. The doping profile can be a profile that decreases along the depth of the dielectric from the surface.

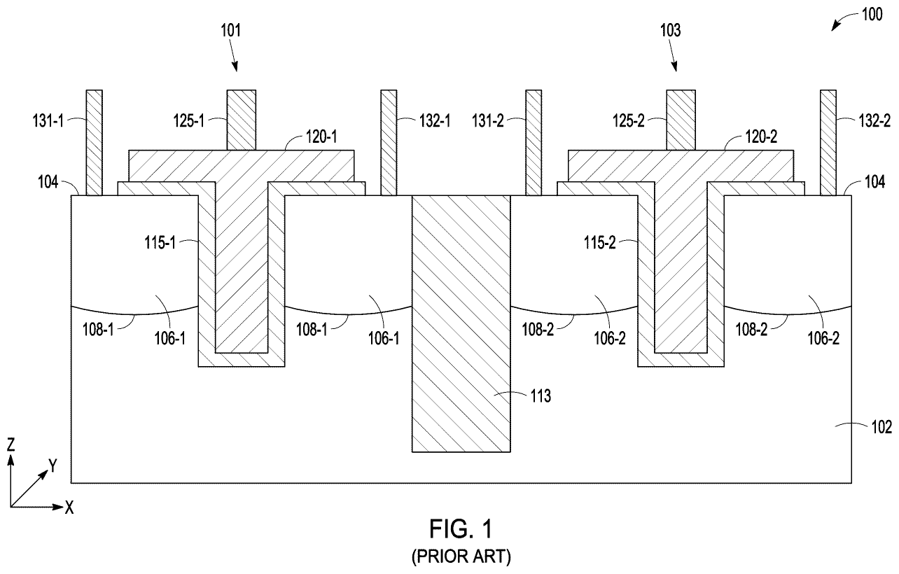

FIG. 1 is a cross-sectional representation of two example capacitors 101 and 103 in an integrated circuit 100 separated from each other by a shallow trench insulator (STI) 113. Capacitors 101 and 103 are structured as two 3D MOS capacitors. Capacitor 101 includes a first conductive region 120-1 separated from a silicon region 102 by a dielectric 115-1 and structured within the walls of dielectric 115-1, where dielectric 115-1 is shaped having a trench-like structure. The trench-like structure is within and surrounded by silicon region 102. Other configurations for the structure of dielectric 115-1 with respect to silicon region 102 can be used. Silicon region 102 has a doping region 106-1 with a doping profile that can decrease from a top surface 104 of silicon region 102 to a doping depth 108-1, which is a junction between a doped region and a substantially undoped region, after which silicon region 102 is undoped, has a net zero doping profile, or is significantly less doped to block intentional current below the bottom of dielectric 115-1. A net zero doping can be realized by having amount of n-type doping substantially equal to an amount of p-type doping. Alternatively, silicon region 102 can have a different doping profile in doping region 106-1 on different sides of dielectric 115-1. Silicon region 102 can be part of a silicon substrate of integrated circuit 100 or a silicon well in another structure within the substrate of integrated circuit 100. First conductive region 120-1 can be a metal or doped polysilicon and dielectric 115-1 can be silicon oxide. First conductive region 120-1 is connected to a contact 125-1 and doping region 106-1 of silicon region 102 at surface 104 of silicon region 102 is connected to a second contact 131-1 and a third contact 132-1, where second contact 131-1 and third contact 132-1 can be held at the same voltage.

Second capacitor 103 can be structured similar to first capacitor 101 with respect to silicon region 102. Capacitor 103 includes a first conductive region 120-2 separated from silicon region 102 by a dielectric 115-2 and structured within the walls of dielectric 115-2, where dielectric 115-2 can be shaped having a trench-like structure. The trench-like structure is within and surrounded by silicon region 102. Other configurations for the structure of dielectric 115-2 with respect to silicon region 102 can be used. The silicon of silicon region 102 has a doping region 106-2 with a doping profile that can decrease from top surface 104 of silicon region 102 to a doping depth 108-2, which is a junction between a doped region and a substantially undoped region, after which silicon region 102 is undoped, has a net zero doping profile, or is significantly less doped to block intentional current below the bottom of dielectric 115-2. Alternatively, silicon region 102 can have a different doping profile in doping region 106-2 on different sides of dielectric 115-2. First conductive region 120-2 can be a metal or doped polysilicon and dielectric 115-2 can be silicon oxide. First conductive region 120-2 is connected to a contact 125-2 and doping region 106-2 of silicon region 102 at surface 104 of silicon region 102 is connected to a second contact 131-2 and a third contact 132-2, where second contact 131-2 and third contact 132-2 can be held at the same voltage. Doping regions 106-1 and 106-2 can have the same doping characteristics and doping depths 108-1 and 108-2 can have the same depth profile. Contacts 131-1 and 131-2 and contacts 132-1 and 132-2 can be configured to be set to the same voltage. STI 113 that separates capacitors 101 and 103 from each other can be a silicon oxide to provide electrical isolation between capacitor 101 and capacitor 103.

Parameters that define the capacitance of capacitors 101 and 103 include the depth of the trench-like structure of the associated capacitor dielectric and the doping depths 108-1 and 108-2, respectively. To structure integrated circuit 100 with increased capacitance of capacitors 101 or 103, the capacitance can be increased by providing a deeper dielectric trench and deeper implants defining doping regions 106-1 and 106-2, respectively. However, the increases in trench depth and deeper doping can conflict with STI trench depth and potentially cause STI isolation leakage issues. With the difference in depths between dielectrics 115-1 and 115-2 and STI 113 and the difference in depths between doping depths 108-1 and 108-2 and STI 113 becoming smaller, a leakage path can be generated from capacitor 101 under STI 113 to capacitor 103. Such a leakage path can also occur in a design of an integrated circuit with another electronic component placed the position of capacitor 103. Creation of such leakage paths in conventional approaches does not allow a mechanism to increase trench depth of 101 and 103 at or beyond the depth of STI 113.

One approach to address isolation leakage can include opening capacitors 101 and 103 to p-type well (PW) implants. However, PW implants into 3D MOS capacitors can raise concerns of oxide reliability of the capacitor dielectric and potentially to C-V characteristics'sensitivity to voltage. With respect to doping profiles in doping regions 106-1 and 106-2, a doping gradient and depletion in doping regions 106-1 and 106-2 causes capacitance to reduce with lower bias, which is not a desirable condition. Optimizing STI isolation leakage with respect to a deep trench for MOS capacitors 101 or 103 can result in bottom of STI 113 not contributing to optimization of the capacitance due to additional well doping or highly graded junctions. Highly graded junctions can result in higher capacitance drop due to depletion, which can be undesirable.

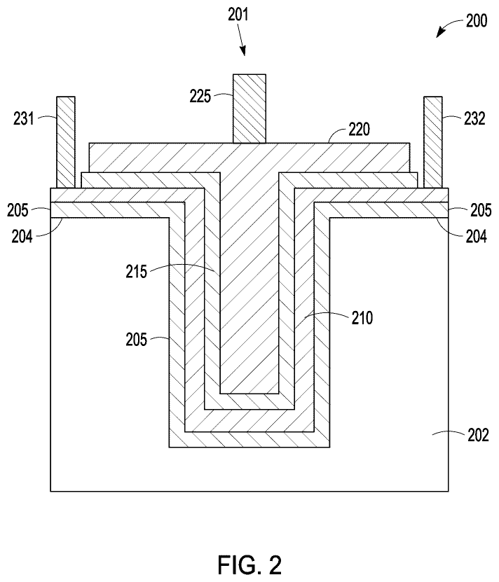

FIG. 2 illustrates an embodiment of an example structure 200 having a capacitor 201 that can be implemented in an integrated circuit without using a semiconductor substrate or well as a component of capacitor 201. Structure 200 includes capacitor 201 in a substrate containing semiconductor material 202. Semiconductor material 202 can be, but is not limited, to silicon. Semiconductor material 202 can be the substrate of the integrated circuit in which capacitor 201 is structured. A first dielectric 205, having a top portion on a top surface 204 of semiconductor material 202 and a portion that extends downward in semiconductor material 202 from the top portion, provides a trench-like structure in which capacitor 201 is located. Capacitor 201 can include a first conductive region 210 on and contacting first dielectric 205, a second dielectric 215 on and contacting first conductive region 210, and a second conductive region 220 on and contacting second dielectric 215. First conductive region 210, second dielectric 215, and second conductive 220 of capacitor 201 can be disposed in the trench-like structure provided by first dielectric 205, filling the trench-like structure. First conductive region 210 or second conductive region 220 can be electrically coupled to a circuit in the integrated circuit in which capacitor 201 is structured.

First conductive region 210 can have a portion on and contacting the top portion of first dielectric 205 that is on top surface 204 of semiconductor material 202. First conductive region 210 connects to contacts 231 and 232 on the portion on and contacting top portion of first dielectric 205 that is on top surface 204 of semiconductor material 202. Contacts 231 and 232 can be coupled to the same voltage. Second dielectric 215 can have a portion on and contacting the portion of first conductive region 210 that is on and contacting the top portion of first dielectric 205. Second conductive region 220 can have a portion on and contacting the portion of second dielectric 215 that is on and contacting the portion of first conductive region 210 that is on the top portion of first dielectric 205 that is on top surface 204 of semiconductor material 202.

Semiconductor material 202 directly adjacent first dielectric 205 can be an undoped region of semiconductor material 202 or a net undoped region of semiconductor material 202. First conductive region 210 and second conductive region 220 can be realized in a number of formats. First conductive region 210 and second conductive region 220 can include doped polysilicon. First conductive region 210 can include a metal and second conductive region 220 can include doped polysilicon. First conductive region 210 can include a metal and second conductive region 220 can include a metal. Second dielectric 215 can be realized by a dielectric oxide such as, but not limited to, silicon oxide (SiO_{X}). Second dielectric 215 can include combinations of dielectric oxides. Second dielectric 215 can be a high-k dielectric, where a high-k dielectric has a dielectric constant greater than the dielectric constant of silicon dioxide. The high-k dielectric can include one or more of hafnium oxide, zirconium oxide, aluminum oxide, a lanthanide oxide, or combinations thereof. Second dielectric 215 can have a thickness selected for a voltage applied to capacitor 201 corresponding to a specification of the integrated circuit in which capacitor 201 is implemented.

Capacitor 201 can be defined by the capacitance across dielectric 215 that separates first conductive region 210 and second region 220, without using semiconductor material 202 as a part of capacitor 201, though capacitor 201 is structured in semiconductor material 202. This structure is in contrast to capacitors 101 and 103 of integrated circuit 100 of FIG. 1 implemented in silicon region 102 with portions of silicon region 102 arranged as a structural component of capacitors 101 and 103. In addition, capacitor 201 can be structured with respect to semiconductor material 202, with the region of semiconductor material 202 adjacent to capacitor 201 and separated from capacitor 201 by first dielectric 205 such that this region of semiconductor material 202 is undoped, so that capacitor 201 can approach a flat capacitance profile over an operational voltage range without concerning leakage through a STI.

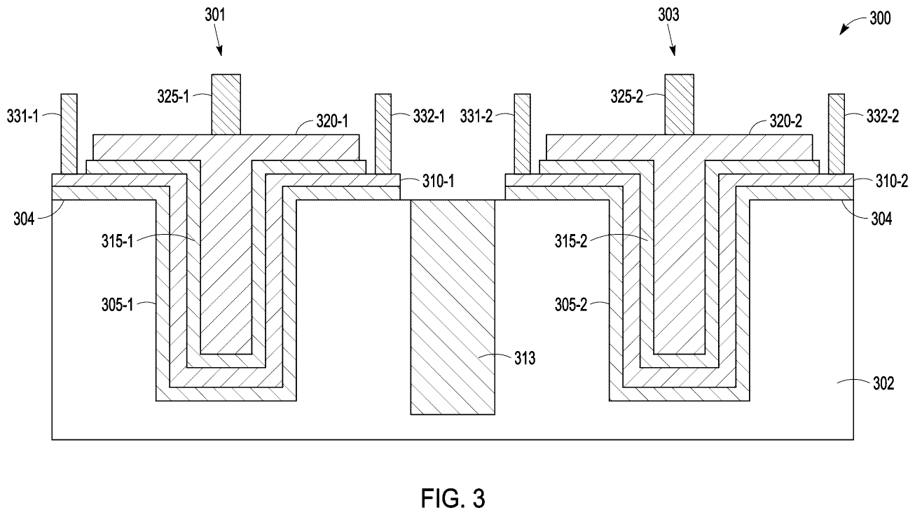

FIG. 3 is a cross-sectional representation of an embodiment of two example capacitors 301 and 303 in an integrated circuit 300 separated from each other by a STI 313, where capacitors 301 and 303 are structured in a semiconductor material 302 without semiconductor material 302 being a part of either capacitor. Semiconductor material 302 can be, but is not limited, to silicon. Semiconductor material 302 can be the substrate of the integrated circuit in which capacitors 301 and 303 are structured. Capacitors 301 and 303 can be structured as two 3D MOS capacitors similar to capacitor 201 of FIG. 2. A first dielectric 305-1 having a top portion on a top surface 304 of semiconductor material 302 and a portion that extends downward in semiconductor material 302 from the top portion provides a trench-like structure in which capacitor 301 can be located. Capacitor 301 can include a first conductive region 310-1 on and contacting first dielectric 305-1, a second dielectric 315-1 on and contacting first conductive region 310-1, and a second conductive region 320-1 on and contacting second dielectric 315-1. First conductive region 310-1, second dielectric 315-1, and second conductive 320-1 of capacitor 301 can be disposed in the trench-like structure provided by first dielectric 305-1, filling the trench-like structure. First conductive region 310-1 or second conductive region 320-1 can be electrically coupled to a circuit in the integrated circuit in which capacitor 301 is structured.

First conductive region 310-1 can have a portion on and contacting the top portion of first dielectric 305-1 that is on top surface 304 of semiconductor material 302. First conductive region 310-1 connects to contacts 331-1 and 332-1 on the portion on and contacting top portion of first dielectric 305-1 that is on top surface 304 of semiconductor material 302. Contacts 331-1 and 332-1 can be coupled to the same voltage. Second dielectric 315-1 can have a portion on and contacting the portion of first conductive region 310-1 that is on and contacting the top portion of first dielectric 305-1. Second conductive region 320-1 can have a portion on and contacting the portion of second dielectric 315-1 that is on and contacting the portion of first conductive region 310-1 that is on the top portion of first dielectric 305-1 that is on top surface 304 of semiconductor material 302.

Semiconductor material 302 directly adjacent first dielectric 305-1 can be an undoped region of semiconductor material 302 or a net undoped region of semiconductor material 302. First conductive region 310-1 and second conductive region 320-1 can be realized in a number of formats. First conductive region 310-1 and second conductive region 320-1 can include doped polysilicon. First conductive region 310-1 can include a metal and second conductive region 320-1 can include doped polysilicon. First conductive region 310-1 can include a metal and second conductive region 320-1 can include a metal. In arrangements with first conductive region 310-1 or second conductive region 320-1 having a metal, the metal can include one or more of tungsten, titanium, titanium nitride, aluminum, molybdenum, a silicide, or a combination of metals. Second dielectric 315-1 can be realized by a dielectric oxide such as, but not limited to, SiO_{X}. Second dielectric 315-1 can include combinations of dielectric oxides. Second dielectric 315-1 can be a high-k dielectric. The high-k dielectric can include one or more of hafnium oxide, zirconium oxide, aluminum oxide, a lanthanide oxide, or combinations thereof. Second dielectric 315-1 can have a thickness selected for a voltage applied to capacitor 301-1 corresponding to a specification of the integrated circuit in which capacitor 301 is implemented. Capacitor 301 can approach a flat capacitance profile over a operational voltage range.

Capacitor 303 can be located in a trench-like structure provided by a first dielectric 305-2. First dielectric 305-2 can have a top portion on top surface 304 of semiconductor material 302 and a portion that extends downward in semiconductor material 302 from the top portion providing the trench-like structure. Capacitor 303 can include a first conductive region 310-2 on and contacting first dielectric 305-2, a second dielectric 315-2 on and contacting first conductive region 310-2, and a second conductive region 320-2 on and contacting second dielectric 315-2. First conductive region 310-2, second dielectric 315-2, and second conductive 320-2 of capacitor 303 can be disposed in the trench-like structure provided by first dielectric 305-2, filling the trench-like structure. First conductive region 310-2 or second conductive region 320-2 can be electrically coupled to a circuit in the integrated circuit in which capacitor 303 is structured.

First conductive region 310-2 can have a portion on and contacting the top portion of first dielectric 305-2 that is on top surface 304 of semiconductor material 302. First conductive region 310-2 connects to contacts 331-2 and 332-2 on the portion on and contacting top portion of first dielectric 305-2 that is on top surface 304 of semiconductor material 302. Contacts 331-2 and 332-2 can be coupled to the same voltage. Second dielectric 315-2 can have a portion on and contacting the portion of first conductive region 310-2 that is on and contacting the top portion of first dielectric 305-2. Second conductive region 320-2 can have a portion on and contacting the portion of second dielectric 315-2 that is on and contacting the portion of first conductive region 310-2 that is on the top portion of first dielectric 305-2 that is on top surface 304 of semiconductor material 302.

Semiconductor material 302 directly adjacent first dielectric 305-2 can be an undoped region of semiconductor material 302 or a net undoped region of semiconductor material 302. First conductive region 310-2 and second conductive region 320-2 can be realized in a number of formats. First conductive region 310-2 and second conductive region 320-2 can include doped polysilicon. First conductive region 310-2 can include a metal and second conductive region 320-2 can include doped polysilicon. First conductive region 310-2 can include a metal and second conductive region 320-2 can include a metal. In arrangements with first conductive region 310-2 or second conductive region 320-2 having a metal, the metal can include one or more of tungsten, titanium, titanium nitride, aluminum, molybdenum, a silicide, or a combination of metals. Second dielectric 315-2 can be realized by a dielectric oxide such as, but not limited to, SiO_{X}. Second dielectric 315-2 can include combinations of dielectric oxides. Second dielectric 315-2 can be a high-k dielectric. The high-k dielectric can include one or more of hafnium oxide, zirconium oxide, aluminum oxide, a lanthanide oxide, or combinations thereof. Second dielectric 315-2 can include combinations of dielectric oxides. Second dielectric 315-2 can have a thickness selected for a voltage applied to capacitor 303 corresponding to a specification of the integrated circuit in which capacitor 303 is implemented. Capacitor 303 can approach a flat capacitance profile over a operational voltage range.

Parameters that define the capacitance of capacitors 301 and 303 include the depth of these capacitors. To structure integrated circuit 300 with increased capacitance of capacitors 301 or 303, the capacitance can be increased by providing a deeper trench-like structure of first dielectric 305-1 or 305-2, respectively. The increases in depth of capacitors 301 or 303 that can have a bottom portion at a level near or below the bottom level of STI 313 that separates capacitors 301 and 303 from each other, without leading to potential leakage from one of the capacitors to the other capacitor around the bottom of STI 313, since the portions of semiconductor material 302 between capacitor 301 and STI 313 and between capacitor 303 and STI 313 are effectively undoped. STI 313 can include SiO_{X} or other appropriate dielectric that can provide electrical isolation and in suitable for processing in integrated circuit 300.

Capacitors 301 and 303 can be constructed as conductor-oxide conductor structures in a semiconductor substrate or semiconductor well for realizing 3D MOS capacitors, where at least the outside conductor is a relatively thin conductive region. Such conductor-oxide-conductor structures can be polysilicon-oxide-polysilicon structures. Such capacitor structures aid in eliminating the use of implants in regions of the semiconductor substrate or semiconductor well directly adjacent the capacitors to control selected increase of the capacitance of these capacitors. With the adjacent semiconductor substrate or well not doped and capacitors in a dielectric trench, there is no issue with respect to STI isolation of capacitor 301 from capacitor 303. With such elimination of doping and STI isolation leakage, the MOS capacitor trench structures of capacitors 301 and 303 can have depths independent of the trench depth of STI 313. With a polysilicon-oxide-polysilicon structure implemented in capacitors 301 or 303, the bottom polysilicon (first conductive region 310-1 or first conductive region 310-2, respectively) can be in-situ doped such that there is no depletion at the boundaries of the bottom polysilicon. The in-situ dopant can be, but is not limited to, phosphorous. The in-situ doped polysilicon of the bottom of capacitor 301 or capacitor 303 can help achieve a flat capacitance-voltage curve.

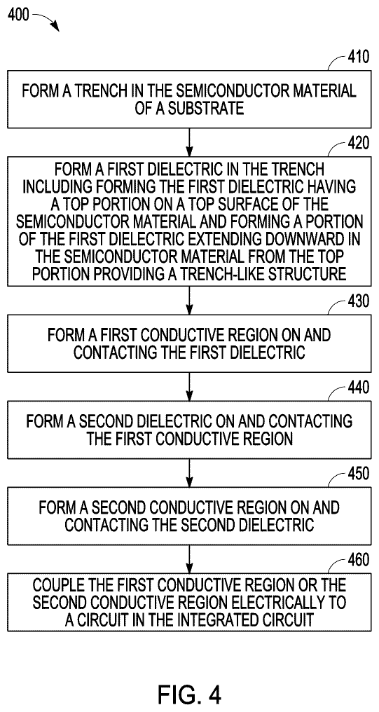

FIG. 4 is a flow diagram of features of an embodiment of an example method 400 of forming an integrated circuit. Method 400 includes creating a capacitor in the integrated circuit that reduces or eliminates use of doping in regions in which the capacitor is formed. At 410, a trench is formed in semiconductor material of a substrate. The semiconductor material can be, but is not limited to, silicon. The semiconductor material can be, but is not limited to, the substrate of the integrated circuit. The substrate can be a substrate for a memory die.

At 420, a first dielectric is formed in the trench. Formation of the first dielectric includes forming the first dielectric having a top portion on a top surface of the semiconductor material and forming a portion of the first dielectric extending downward in the semiconductor material providing a trench-like structure. In formation of the integrated circuit, a capacitor is formed in the trench-like structure. The capacitor in the trench-like structure can be formed in the periphery to a memory array of memory cells of a memory die.

At 430, in formation of the capacitor, a first conductive region is formed on and contacting the first dielectric. At 440, in formation of the capacitor, a second dielectric is formed on and contacting the first conductive region. At 450, in the formation of the capacitor, a second conductive region is formed on and contacting the second dielectric, such that the first conductive region, the second dielectric, and the second conductive region are in the trench-like structure. At 460, the first conductive region or the second conductive region is electrically coupled to a circuit in the integrated circuit.

Variations of method 400 or methods similar to method 400 can include a number of different embodiments that may be combined depending on the application of such methods or the architecture or operational flow for which such methods are implemented. Such methods can include forming the first conductive region by forming polysilicon that is in-situ doped. The in-situ doping can include doping with phosphorous or other element suitable for providing the polysilicon with low resistivity. Variations can include forming the first conductive region by forming a metal as the first conductive region. Variations can include forming the second conductive region by forming polysilicon. Variations can include forming the second conductive region by forming a metal as the second conductive region. Variations can include forming polysilicon as one of the first conductive region or the second conductive region and forming the other one of the first conductive region or the second conductive region by forming a metal.

Variations can include patterning and etching the second conductive region and forming connections from the second conductive region to a circuit of the integrated circuit. Variations can include, after forming the second conductive region, forming contacts to the capacitor, and forming electrical insulators to the contacts and to the exposed surfaces of the first and second conductive regions by a high aspect ratio process.

In various embodiments, an integrated circuit can comprise a substrate containing semiconductor material, a first dielectric having a top portion on a top surface of the semiconductor material and a portion that extends downward in the semiconductor material from the top portion providing a trench-like structure; and a capacitor in the trench-like structure. The capacitor can have a first conductive region on and contacting the first dielectric; a second dielectric on and contacting the first conductive region; and a second conductive region on and contacting the second dielectric. The first conductive region, the second dielectric, and the second conductive are disposed in the trench-like structure. The first conductive region or the second conductive region are electrically coupled to a circuit in the integrated circuit. The integrated circuit can include an electronic component in the semiconductor material and a STI in the semiconductor material positioned between the capacitor and the electronic component, electrically isolating the capacitor from the electronic component.

Variations of such an integrated circuit and its features can include a number of different embodiments and features that may be combined depending on the application of such integrated circuits, the format of such integrated circuits, and/or the architecture in which such integrated circuits are implemented. Features of such integrated circuits can include a top surface of the STI being at the top surface of the semiconductor material. Portion of the semiconductor material between the STI and the capacitor can be undoped such that depth of the capacitor is independent of depth of the STI to maintain lack of leakage due to STI isolation. The capacitor in the integrated circuit can have a flat capacitance-voltage roll-off in an operational voltage range. Variations can include the second dielectric having a thickness selected for a voltage applied to the capacitor corresponding to a specification of the integrated circuit. The thickness can be relatively large for a high voltage application in the range of about 20 V to about 50 V. The thickness can be relatively small for a low voltage application in the range less than 10 V. For a low voltage application, the thickness can be equal to or less than about 5.5 nanometers or equal to or less than 2.5 nanometers. For higher voltage application, the thickness can be greater than the thickness for low voltage applications.

Variations can include the electronic component being another capacitor structured similar to the capacitor. The electronic component can be another passive device. Passive devices or components do not generate energy, amplify, or generate signals, but can store it or dissipate it. The electronic component can be an active device such as, but not limited to, a diode or a transistor. Variations can include the integrated circuit being a memory device, with the capacitor configured as part of a circuit in a periphery to a memory array of the memory device.

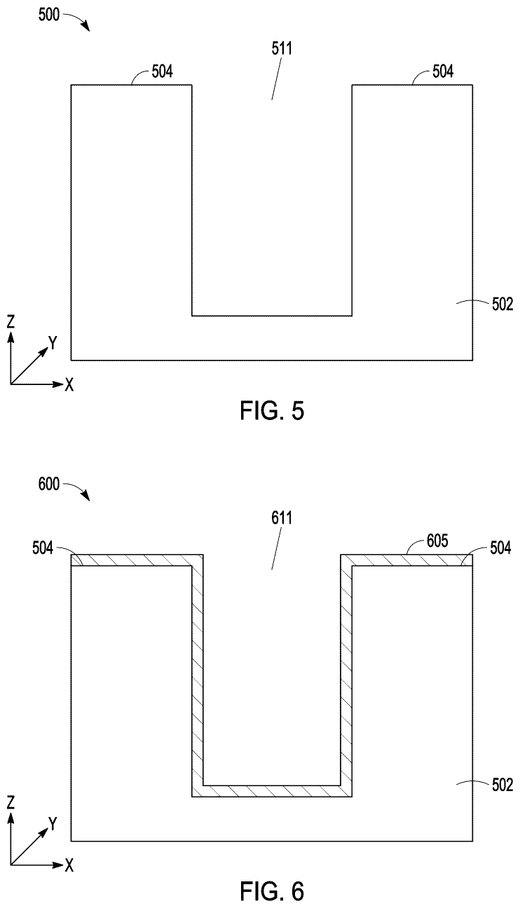

FIGS. 5-11 represent an embodiment of an example process flow of forming a 3D MOS capacitor in a portion of an integrated circuit such that the 3D MOS capacitor does not include the portion of the integrated circuit as a component of the 3D MOS capacitor. The 3D MOS capacitor can be constructed in a periphery to a memory array in a memory device. Though formation of one 3D MOS capacitor is shown in the process flow of FIGS. 5-11, significantly more than one 3D MOS capacitor can be formed while forming the 3D MOS capacitor of the process flow of FIGS. 5-11.

FIG. 5 shows a cross-sectional view of a structure 500 after an opening 511 has been formed in a semiconductor material 502 having a top surface 504. Semiconductor material 502 can be substrate of an integrated circuit. In another variation, semiconductor material 502 can be a semiconductor well in the substrate for the integrated circuit. Semiconductor material 502 can be, but is not limited to, silicon.

FIG. 6 shows a cross-sectional view of a structure 600 after processing structure 500 of FIG. 5. A dielectric 605 has been formed in opening 511 with the top of dielectric 605 on surface 504 with dielectric 605 extending from the dielectric 605 on surface 504 along the surfaces of opening 511, reducing opening 511 to opening 611. Dielectric 605 can be, but is not limited to, deposited or grown SiO_{X}. Dielectric 605 with opening 611 forms a trench in semiconductor material 502.

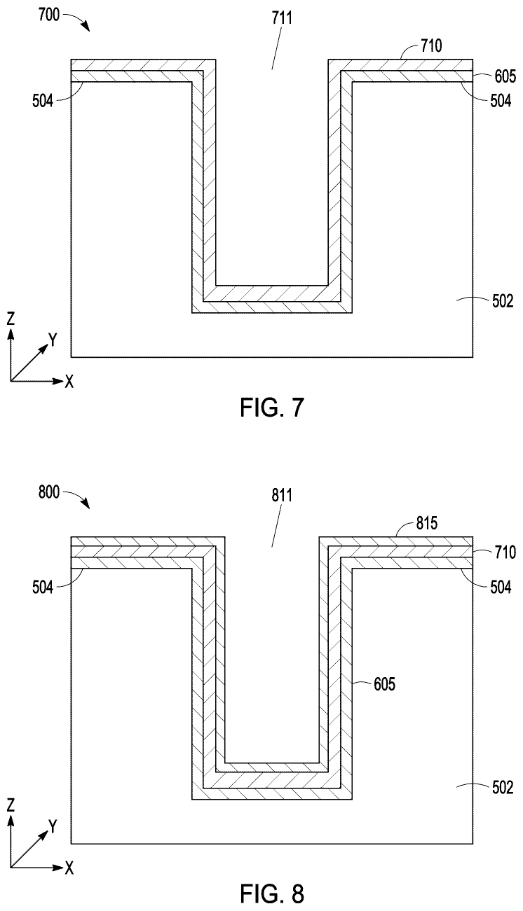

FIG. 7 shows a cross-sectional view of a structure 700 after processing structure 600 of FIG. 6. A conductive region 710 has been formed on and contacting dielectric 605, including on and contacting the portion of dielectric 605 that is on surface 504 and along the entire surface of dielectric 605 in opening 611. Conductive region 710 generates the bottom of the capacitor being formed. Conductive region 710 can be formed as polysilicon. The polysilicon can be in-situ doped polysilicon. The dopant can be, but is not limited to, phosphorous. Alternatively, conductive region 710 can be a metal formed by a method appropriate for the metal. The metal can be, but is not limited to, one or more of tungsten, titanium, titanium nitride, aluminum, molybdenum, a silicide, or a combination of metals. Formation of conductive region 710 has reduced opening 611 of structure 600 to an opening 711.

FIG. 8 shows a cross-sectional view of a structure 800 after processing structure 700 of FIG. 7. A dielectric 815 has been formed on and contacting conductive region 710, including on and contacting the portion of conductive 710 that is on dielectric 605 that is on surface 504 and along the entire surface of conductive region 710 in opening 711 of structure 700. Dielectric 815 can be formed by a method appropriate for the material of dielectric 815. Dielectric 815 can be, but is not limited to, SiO_{X}, a high-k dielectric, or combinations of dielectric oxides. The high-k dielectric can include one or more of hafnium oxide, zirconium oxide, aluminum oxide, a lanthanide oxide, or combinations thereof. For formation of SiOₓ as dielectric 815, SiO_{X} can be attained by liquid vapor (LV) growth. Formation of dielectric 815 has reduced opening 711 of structure 700 to an opening 811, maintaining a trench, having the combination of dielectric 815, conductive region 710, and dielectric 605 as sidewalls, in semiconductor material 502.

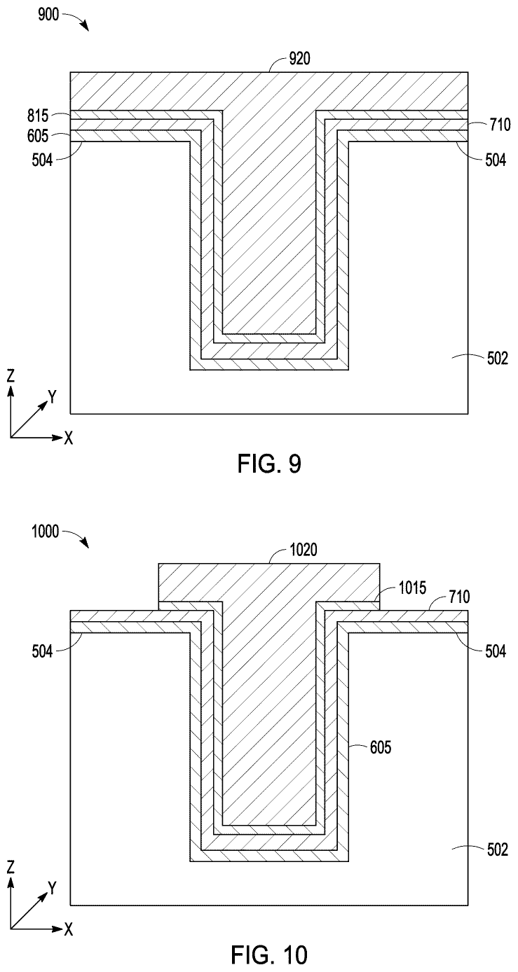

FIG. 9 shows a cross-sectional view of a structure 900 after processing structure 800 of FIG. 8. Conductive material 920 has been formed in opening 811 of structure 800, filling the opening. Conductive material 920 has also been formed on dielectric 815 that is on and contacting the portion of conductive 710 that is on dielectric 605 that is on surface 504. Conductive material 920 can be formed as polysilicon. The polysilicon can be formed as deposited polysilicon that can be doped during deposition or after forming the polysilicon. Alternatively, conductive material 920 can be formed as a metal region, which the metal region can include one or more of tungsten, titanium, titanium nitride, aluminum, molybdenum, a silicide, or a combination of metals. Conductive material 920 can be formed by a method appropriate for the material being structured on dielectric 815.

FIG. 10 shows a cross-sectional view of a structure 1000 after processing structure 900 of FIG. 9. Patterning has been conducted for removing portions of conductive material 920 and dielectric 815. Conductive material 920 and dielectric 815 have been etched, forming conductive region 1020 on and contacting dielectric 1015. Dielectric 1015 has been constructed to be a capacitor dielectric sandwiched between conductive region 1020 and conductive region 710.

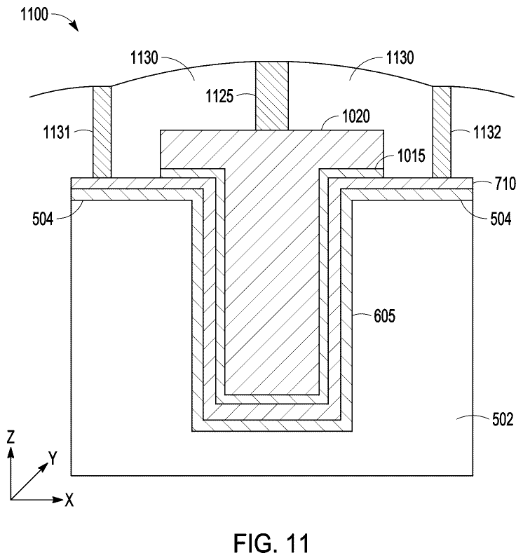

FIG. 11 shows a cross-sectional view of a structure 1100 after processing structure 1000 of FIG. 10. Contacts 1131 and 1132 have been formed on top surfaces of conductive region 710. Contacts 1131 and 1132 can be coupled to a common voltage. A contact 1125 has been formed on a top surface of conductive region 1020. An electrical insulator 1130 has been formed between and covering conductive components of structure 1100. Electrical insulator 1130 can be formed by a high aspect ratio process, which is a non-plasma based chemical vapor deposition (CVD) process.

Example process flow of FIGS. 5-11 can be used to construct other 3D MOS trench capacitors in the integrated circuit in which a trench capacitor, structured as conductive region 1020-dielectric 1015-conductive region 710, is constructed. The 3D MOS trench capacitor can be, but is not limited to, a polysilicon-dielectric-polysilicon capacitor. The other 3D MOS capacitors can be formed simultaneously with this capacitor with the same design. Other portions of the integrated circuit, for which the 3D MOS trench capacitor is constructed, can be formed after forming the capacitor to complete the fabrication of the integrated circuit.

Various deposition techniques for components of structures in the process flows discussed above or similar structures and process flows can be used that are typical for the material being formed, the dimensions of the material being formed, and the architecture in which the material is being formed. Processes for forming the various materials can include, but are not limited to, CVD, atomic layer deposition (ALD), and physical vapor deposition (PVD). PVD can include, but is not limited to, sputtering, ion beam deposition, electron beam evaporation, pulsed laser deposition, and vacuum arc methods, among others. CVD can include, but is not limited to, plasma chemical vapor deposition and laser chemical vapor deposition, among others. Selective etching and conventional masking techniques can be used to remove selected regions in the processing. Etching procedures can include, but are not limited to, wet etching, dry etching, and atomic layer etching deposition, among others. Formation of other components of an integrated circuit such a memory die are not shown to focus on formation of 3D MOS capacitors that can have depths independent of the depths of STIs isolating the 3D MOS capacitors in the integrated circuit. The integrated circuit can be a memory die in which 3D MOS capacitors can be configured in a circuit in a periphery to a memory array region of the memory die. The memory die can be, but is not limited to, a NAND memory device.

Electronic devices, such as mobile electronic devices (e.g., smart phones, tablets, etc.), electronic devices for use in automotive applications (e.g., automotive sensors, control units, driver-assistance systems, passenger safety or comfort systems, etc.), and internet-connected appliances or devices (e.g., internet-of-things (IoT) devices, etc.), have varying storage needs depending on, among other things, the type of electronic device, use environment, performance expectations, etc. Such electronic devices can be broken down into several main components: a processor (e.g., a central processing unit (CPU) or other main processor); memory (e.g., one or more volatile or nonvolatile RAM memory device, such as DRAM, mobile or low-power double-data-rate synchronous DRAM (DDR SDRAM), etc.); and a storage device (e.g., non-volatile memory (NVM) device, such as flash memory, ROM, a solid-state drive (SSD), a MultiMediaCard (MMC), or other memory card structure or assembly, etc.). In certain examples, electronic devices can include a user interface (e.g., a display, touch-screen, keyboard, one or more buttons, etc.), a graphics processing unit (GPU), a power management circuit, a baseband processor or one or more transceiver circuits, etc. As used herein, “processor device” means any type of computational circuit such as, but not limited to, a microprocessor, a microcontroller, a graphics processor, a digital signal processor (DSP), or any other type of processor or processing circuit, including a group of processors or multi-core devices. These electronic devices provide examples of structures that can include 3D MOS capacitors for circuits, as taught herein, in a periphery to a memory array within the electronic devices or in other integrated circuits within the electronic devices.

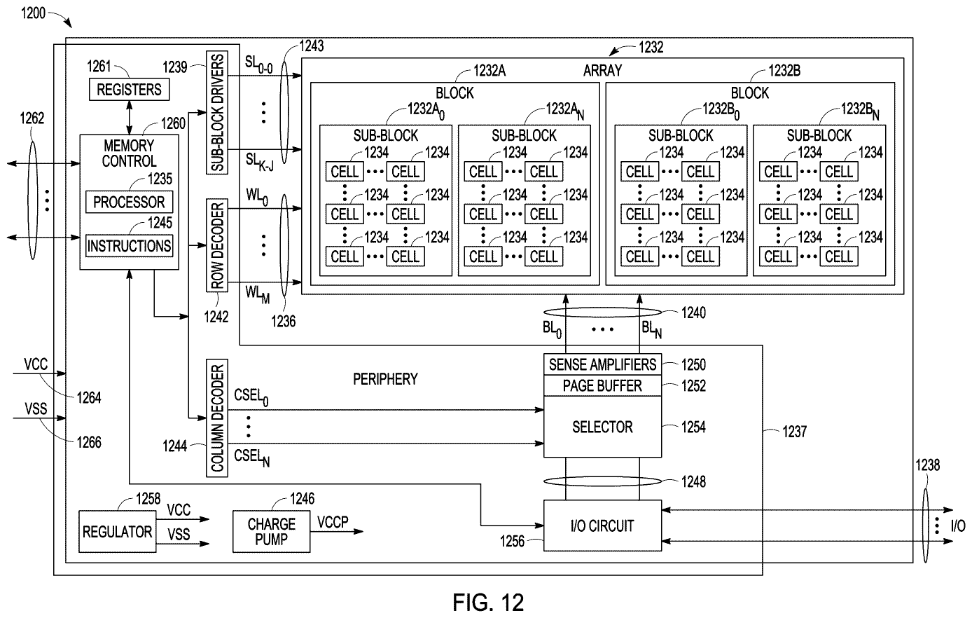

FIG. 12 is a schematic of an embodiment of an example memory device 1200 that can include an architecture in which 3D MOS capacitors, as taught herein, are structured in a periphery 1237 to a memory array 1232 of memory device 1200. Memory device 1200 can be, but is not limited to, a NAND memory device. Memory device 1200 can include memory array 1232 having a plurality of memory cells 1234 and periphery 1237 to memory array 1232, where periphery 1237 can include sense amplifiers 1250, and one or more circuits or components to provide communication with memory array 1232 or perform one or more memory operations on memory array 1232. Memory device 1200 can include one or more 3D MOS capacitors in periphery 1237 constructed having a structure as discussed with respect to FIG. 2, FIG. 3, or FIG. 11. Memory cells 1234 can be formed coupled to data lines, where these data lines couple to or are a part of data lines (BLs) 1240 coupled to sense amplifiers 1250. Memory device 1200 can be a memory die, for example, a NAND memory die. Periphery 1237 of memory device 1200 can include a row decoder 1242, a column decoder 1244, sub-block drivers 1239, sense amplifiers 1250, a page buffer 1252, a selector 1254, an I/O circuit 1226, a regulator 1258, a charge pump 1246, and a memory controller 1260.

Memory controller 1260 can include processing circuitry, including one or more processors 1235, and can be configured to perform operations of the memory device 1200 by executing instructions 1245. Memory controller 1260 can be coupled to registers 1261 that can contain parameter data for memory controller 1260. For purposes of the present example, instructions 1245 may be performed by memory within or dedicated to memory controller 1260. In other examples, at least some portion of the instructions executed by memory controller 1260 may be stored in other memory structures and loaded, for example, into local (memory controller) memory for execution by the memory controller 1260.

Memory cells 1234 of memory array 1232 can be arranged in blocks, such as first and second blocks 1232A, 1232B. Each block can include sub-blocks. For example, first block 1232A can include first and second sub-blocks 1232A₀, 1232A_{N}, and second block 1232B can include first and second sub-blocks 1232B₀, 1232B_{N}. Each sub-block can include a number of physical pages, with each page including a number of memory cells 1234. Although illustrated herein as having two blocks, with each block having two sub-blocks, and each sub-block having a number of memory cells 1234, in other examples, the memory array 1232 can include more or fewer blocks, sub-blocks, memory cells, etc. In other examples, the memory cells 1234 can be arranged in a number of rows, columns, pages, sub-blocks, blocks, etc., and accessed using, for example, access lines 1236, data lines 1240, or one or more select gates, source lines, etc.

Memory controller 1260 can control memory operations of the memory device 1200 according to one or more signals or instructions received on control lines 1262, including, for example, one or more clock signals or control signals that indicate a desired operation (e.g., write, read, erase, etc). One or more devices external to memory device 1200 can control the values of the control signals on control lines 1262. Examples of devices external to memory device 1200 can include, but are not limited to, a host, an external memory controller, a processor, or one or more circuits or components not illustrated in FIG. 12.

Memory device 1200 can use data lines 1240 to transfer data to (e.g., write or erase) or from (e.g., read) one or more of memory cells 1234. Row decoder 1242 and column decoder 1244 can receive and decode address signals from memory control 1260 operating with I/O circuit 1256 that can control input of commands, addresses, and data input over I/O line 1238. Row decoder 1242 and column decoder 1244 can provide signals to one or more of access lines 1236 (e.g., one or more of a plurality of access lines (WL₀-WL_{M})) or data lines 1240 (e.g., one or more of a plurality of data lines (BL0-BLN)). Memory device 1200 can include sense circuitry, such as selector 1254, page buffer 1252, and sense amplifiers 1250, configured to determine the values of data on (e.g., read), or to determine the values of data to be written to, memory cells 1234 using data lines 1240.

One or more devices external to the memory device 1200 can communicate with memory device 1200 using I/O lines 238 or control lines 1262. I/O circuit 1256 can transfer values of data in or out of memory device 1200, such as in or out of page buffer 1252 or memory array 1232, using I/O lines 1238, according to, for example, control lines 1262. Page buffer 1252 can store data received from the one or more devices external to memory device 1200 before the data is programmed into relevant portions of memory array 1232, or can store data read from memory array 1232 before the data is transmitted to the one or more devices external to the memory device 1200.

Column decoder 1244 can receive and decode address signals into one or more column select signals (CSEL₁-CSEL_{N}). Selector 1254 (e.g., a select circuit) can receive the column select signals (CSEL₁-CSEL_{N}) and select data in page buffer 1252 representing values of data to be read from or to be programmed into memory cells 1234. Selected data can be transferred between page buffer 1252 and the I/O circuit 1226 using second data lines 1248.

Memory controller 1260 can receive positive and negative supply signals, such as a supply voltage (Vcc) 1264 and a negative supply (Vss) 1266 (e.g., a ground potential) with respect to Vcc, from an external source or supply (e.g., an internal or external battery, an alternating current (AC) to direct current (DC) converter, etc.). In certain examples, memory controller 1260 can include a regulator 1258 to internally provide positive or negative supply signals. Charge pump 1246 can generate an output signal, Vccp, to provide high voltages to one or more components of memory device 1200. Vccp is high relative to logic voltages for array 1232. Charge pump 1246, page buffer 1252, sense amplifiers 1250, or one or more components of periphery 1237 can be structured having 3D MOS capacitors, as taught herein.

Based on an address provided by a user device, memory controller 1260 can select any one sub-block or all sub-blocks. Memory controller 1260 can generate the sub-block address to the sub-block drivers 1239 and select any one sub-block or all sub-blocks. Memory controller 1260 can send the WL information to the row decoder 1242 and a column address to the column decoder 1244.

Sub-block drivers 1239 can include a number of independent drivers that generate signals to select lines 1243 SL₀₋₀ . . . SL_{K-J}. These select lines can be coupled to different select devices in different blocks. Multiple input signals can be assigned to each individual driver, depending on the different voltages designed for operation of the respective driver during erase operations, program operations, and read operations. From the sub-block drivers 1239, appropriate operational signals can be sent to the memory array 1232 via the select lines 1243 (SL_{(sub-block#)-(SGD# or SGS#)} SL₀₋₀ . . . SL_{K-J}.

The following are example embodiments of devices and methods, in accordance with the teachings herein.

An example memory device 1 can comprise: a substrate containing semiconductor material; a first dielectric having a top portion on a top surface of the semiconductor material and a portion that extends downward in the semiconductor material from the top portion providing a trench-like structure; and a capacitor in the trench-like structure. The capacitor has a first conductive region on and contacting the first dielectric; a second dielectric on and contacting the first conductive region; and a second conductive region on and contacting the second dielectric, where the first conductive region, the second dielectric, and the second conductive are disposed in the trench-like structure, with the first conductive region or the second conductive region electrically coupled to a circuit in the memory device.

An example memory device 2 can include features of example memory device 1 and can include the first conductive region having a portion on and contacting the top portion of the first dielectric and connects to a contact on the portion on and contacting the top portion of the first dielectric.

An example memory device 3 can include features of example memory device 2 and example memory device 1 and can include the second dielectric having a portion on and contacting the portion of the first conductive region that is on and contacting the top portion of the first dielectric; and the second conductive region having a portion on and contacting the portion of the second dielectric that is on and contacting the portion of the first conductive region that is on the top portion of the first dielectric.

An example memory device 4 can include features of any of the preceding example memory devices and can include the semiconductor material directly adjacent the first dielectric being a net undoped region of the semiconductor material.

An example memory device 5 can include features of any of the preceding example memory devices and can include the semiconductor material being a substrate of the memory device.

An example memory device 6 can include features of any of the preceding example memory devices and can include the first conductive region and the second conductive region having doped polysilicon.

An example memory device 7 can include features of any of the preceding example memory devices and can include the first conductive region having a metal and the second conductive region having doped polysilicon.

An example memory device 8 can include features of any of the preceding example memory devices and can include the second dielectric having a thickness selected for a voltage applied to the capacitor corresponding to a specification of the memory device.

An example memory device 9 can include features of any of the preceding example memory devices and can include the capacitor being arranged in a page buffer of the memory device or in a charge pump of the memory device.

In an example memory device 10, any of the memory devices of example memory devices 1 to 9 may be incorporated into an electronic apparatus further comprising a host processor or memory controller and a communication bus extending between the host processor/memory controller and the memory device.

In an example memory device 11, any of the memory devices of example memory devices 1 to 10 may be modified to include any structure presented in another of example memory device 1 to 10.

In an example memory device 12, any apparatus associated with the memory devices of example memory devices 1 to 11 may further include a machine-readable storage device configured to store instructions as a physical state, wherein the instructions may be used to perform one or more operations of the apparatus.

In an example memory device 13, any of the memory devices of example memory devices 1 to 12 may be formed or operated in accordance with any of the below example methods 1 to 8.

An example integrated circuit 1 can comprise: a substrate containing semiconductor material; a first dielectric having a top portion on a top surface of the semiconductor material and a portion that extends downward in the semiconductor material from the top portion providing a trench-like structure; a capacitor in the trench-like structure, the capacitor having: a first conductive region on and contacting the first dielectric; a second dielectric on and contacting the first conductive region; and a second conductive region on and contacting the second dielectric, the first conductive region, the second dielectric, and the second conductive disposed in the trench-like structure, with the first conductive region or the second conductive region electrically coupled to a circuit in the integrated circuit; an electronic component in the semiconductor material; and a STI in the semiconductor material, the STI positioned between the capacitor and the electronic component, electrically isolating the capacitor from the electronic component.

An example integrated circuit 2 can include features of example integrated circuit 1 and can include a top surface of the STI being at the top surface of the semiconductor material.

An example integrated circuit 3 can include features of any of the preceding example integrated circuits 1 to 2 and can include portion of the semiconductor material between the STI and the capacitor being undoped such that depth of the capacitor is independent of depth of the STI to maintain lack of leakage below STI isolation.

An example integrated circuit 4 can include features of any of the preceding example integrated circuits 1 to 3 and can include the electronic component being another capacitor structured similar to the capacitor.

An example integrated circuit 5 can include features of any of the preceding example integrated circuits 1 to 4 and can include the capacitor in the integrated circuit having an operational voltage range and the capacitor has a flat capacitance-voltage roll-off in the operational voltage range.

An example integrated circuit 6 can include features of any of the preceding example integrated circuits 1 to 5 and can include the second dielectric having a thickness selected for a voltage applied to the capacitor corresponding to a specification of the integrated circuit.

An example integrated circuit 7 can include features of any of the preceding example integrated circuits 1 to 6 and can include the integrated circuit being a memory device and the capacitor being part of a circuit in a periphery to a memory array of the memory device.

In an example integrated circuit 8, any of the integrated circuits of example integrated circuits 1 to 7 may be incorporated into an electronic apparatus further comprising a host processor or memory controller and a communication bus extending between the host processor/memory controller and the integrated circuit.

In an example integrated circuit 9, any of the integrated circuits of example integrated circuits 1 to 8 may be modified to include any structure presented in another of example integrated circuit 1 to 8.

In an example integrated circuit 10, any apparatus associated with the integrated circuits of example integrated circuits 1 to 9 may further include a machine-readable storage device configured to store instructions as a physical state, wherein the instructions may be used to perform one or more operations of the apparatus.

In an example integrated circuit 11, any of the integrated circuits of example integrated circuits 1 to 10 may be formed or operated in accordance with any of the below example methods 1 to 8.

An example method 1 of forming an integrated circuit can comprise: forming a trench in semiconductor material of a substrate; forming a first dielectric in the trench including forming the first dielectric having a top portion on a top surface of the semiconductor material and forming a portion of the first dielectric extending downward in the semiconductor material from the top portion providing a trench-like structure; forming a capacitor in the trench-like structure, forming the capacitor including: forming a first conductive region on and contacting the first dielectric; forming a second dielectric on and contacting the first conductive region; and forming a second conductive region on and contacting the second dielectric, the such that the first conductive region, the second dielectric, and the second conductive region are in the trench-like structure; and coupling the first conductive region or the second conductive region electrically to a circuit in the integrated circuit.

An example method 2 of forming an integrated circuit can include features of example method 1 of forming an integrated circuit and can include forming the first conductive region by forming polysilicon that is in-situ doped.

An example method 3 of forming an integrated circuit can include features of any of the preceding example methods of forming an integrated circuit and can include forming the second conductive region to include patterning and etching the second conductive region and forming connections from the second conductive region to a circuit of the integrated circuit.

An example method 4 of forming an integrated circuit can include features of any of the preceding example methods of forming an integrated circuit and can include, after forming the second conductive region: forming contacts to the capacitor; and forming electrical insulators to the contacts and exposed surfaces of the first and second conductive regions by a high aspect ratio process.

In an example method 5, any of the example methods 1 to 4 of forming an integrated circuit may be performed in forming an electronic apparatus further comprising a host processor and a communication bus extending between the host processor and a memory system.

In an example method 6 of forming an integrated circuit, any of the example methods 1 to 5 of forming an integrated circuit may be modified to include operations set forth in any other of example methods 1 to 5.

In an example method 7 of forming an integrated circuit, any of the example methods 1 to 6 of forming an integrated circuit may be implemented at least in part through use of instructions stored as a physical state in one or more machine-readable storage devices.

An example method 8 of forming an integrated circuit can include features of any of the preceding example methods 1 to 7 of forming an integrated circuit and can include performing functions associated with any features of example memory devices 1 to 13 or example integrated circuits 1 to 11.

An example machine-readable storage device storing instructions, that when executed by one or more processors, cause a machine to perform operations, can comprise instructions to perform functions associated with any features of example memory devices 1 to 13, any features of example integrated circuits 1 to 11or perform methods associated with any features of example methods 1 to 8 of forming an integrated circuit.

Although specific embodiments have been illustrated and described herein, it will be appreciated by those of ordinary skill in the art that any arrangement that is calculated to achieve the same purpose can be substituted for the specific embodiments shown. Various embodiments use permutations and/or combinations of embodiments described herein. It is to be understood that the above description is intended to be illustrative, and not restrictive, and that the phraseology or terminology employed herein is for the purpose of description.

What is claimed is:

1. A memory device comprising:
a substrate containing semiconductor material;
a first dielectric having a top portion on a top surface of the semiconductor
material and a portion that extends downward in the semiconductor material from the top portion providing a trench-like structure; and
a capacitor in the trench-like structure, the capacitor having:
a first conductive region on and contacting the first dielectric;
a second dielectric on and contacting the first conductive region; and
a second conductive region on and contacting the second dielectric, the first conductive region, the second dielectric, and the second conductive disposed in the trench-like structure, with the first conductive region or the second conductive region electrically coupled to a circuit in the memory device.

2. The memory device of claim 1, wherein the first conductive region has a portion on and contacting the top portion of the first dielectric and connects to a contact on the portion on and contacting the top portion of the first dielectric.

3. The memory device of claim 2, wherein:
the second dielectric has a portion on and contacting the portion of the first conductive region that is on and contacting the top portion of the first dielectric; and
the second conductive region has a portion on and contacting the portion of the second dielectric that is on and contacting the portion of the first conductive region that is on the top portion of the first dielectric.

4. The memory device of claim 1, wherein the semiconductor material directly adjacent the first dielectric is a net undoped region of the semiconductor material.

5. The memory device of claim 1, wherein the semiconductor material is a substrate of the memory device.

6. The memory device of claim 1, wherein the first conductive region and the second conductive region include doped polysilicon.

7. The memory device of claim 1, wherein the first conductive region includes a metal and the second conductive region includes doped polysilicon.

8. The memory device of claim 1, wherein the second dielectric has a thickness selected for a voltage applied to the capacitor corresponding to a specification of the memory device.

9. The memory device of claim 1, wherein the capacitor is arranged in a page buffer of the memory device or in a charge pump of the memory device.

10. An integrated circuit comprising:
a substrate containing semiconductor material;
a first dielectric having a top portion on a top surface of the semiconductor
material and a portion that extends downward in the semiconductor material from the top portion providing a trench-like structure;
a capacitor in the trench-like structure, the capacitor having:
a first conductive region on and contacting the first dielectric;
a second dielectric on and contacting the first conductive region; and
a second conductive region on and contacting the second dielectric, the first conductive region, the second dielectric, and the second conductive disposed in the trench-like structure, with the first conductive region or the second conductive region electrically coupled to a circuit in the integrated circuit;
an electronic component in the semiconductor material; and
a shallow trench insulator (STI) in the semiconductor material, the STI
positioned between the capacitor and the electronic component, electrically isolating the capacitor from the electronic component.

11. The integrated circuit of claim 10, wherein a top surface of the STI is at the top surface of the semiconductor material.

12. The integrated circuit of claim 10, wherein portion of the semiconductor material between the STI and the capacitor is undoped such that depth of the capacitor is independent of depth of the STI to maintain lack of leakage below STI isolation.

13. The integrated circuit of claim 10, wherein the electronic component is another capacitor structured similar to the capacitor.

14. The integrated circuit of claim 10, wherein the capacitor in the integrated circuit has an operational voltage range and the capacitor has a flat capacitance-voltage roll-off in the operational voltage range.

15. The integrated circuit of claim 10, wherein the second dielectric has a thickness selected for a voltage applied to the capacitor corresponding to a specification of the integrated circuit.

16. The integrated circuit of claim 10, wherein the integrated circuit is a memory device and the capacitor is part of a circuit in a periphery to a memory array of the memory device.

17. A method of forming an integrated circuit, the method comprising:
forming a trench in semiconductor material of a substrate;
forming a first dielectric in the trench including forming the first dielectric having a top portion on a top surface of the semiconductor material and forming a portion of the first dielectric extending downward in the semiconductor material from the top portion providing a trench-like structure;
forming a capacitor in the trench-like structure, forming the capacitor including:
forming a first conductive region on and contacting the first dielectric;
forming a second dielectric on and contacting the first conductive region; and
forming a second conductive region on and contacting the second dielectric such that the first conductive region, the second dielectric, and the second conductive region are in the trench-like structure; and
coupling the first conductive region or the second conductive region electrically to a circuit in the integrated circuit.

18. The method of claim 17, wherein forming the first conductive region includes forming polysilicon that is in-situ doped.

19. The method of claim 17, wherein forming the second conductive region includes patterning and etching the second conductive region and forming connections from the second conductive region to a circuit of the integrated circuit.

20. The method of claim 17, wherein the method includes, after forming the second conductive region:
forming contacts to the capacitor; and
forming electrical insulators to the contacts and exposed surfaces of the first and second conductive regions by a high aspect ratio process.
